(19) United States
(12) Patent Application Publication
(10) Pub. No.: US 2026/0231387 A1
(43) Pub. Date: Aug. 6, 2026

(54) SEMICONDUCTOR DEVICE

(71) Applicant: TAIWAN SEMICONDUCTOR MANUFACTURING COMPANY LTD., HSINCHU (TW)

(72) Inventor: JHON JHY LIAW, HSINCHU COUNTY (TW)

(21) Appl. No.: 19/047,551

(22) Filed: Feb. 6, 2025

(51) Int. Cl. H10B 10/00

(52) U.S. Cl. CPC H10B 10/125

(57) ABSTRACT

A semiconductor device is provided. In a first memory cell, a first pass-gate transistor has a first gate structure electrically connected to a first word line and a source/drain feature electrically connected to a first bit line, and a first pull-up transistor has a source electrically connected to a first VDD line. In a second memory cell, a second pass-gate transistor has a second gate structure electrically connected to a second word line and a source/drain feature electrically connected to a second bit line, and a second pull-up transistor has a source electrically connected to a second VDD line. The first and second VDD lines and the first bit line are disposed in a first metal layer closest to the first and second gate structures, and the first word line and the second bit line are disposed in a second metal layer over the first metal layer.

### BACKGROUND

Advances in the integrated circuit (IC) industry have resulted in smaller and more complex circuits than the previous generation, which, however, have commensurately increased complexity of processing and manufacturing. In the course of IC evolution, functional density (i.e., the number of interconnected devices per chip area) has generally increased while geometric size (i.e., the smallest component that can be created using a fabrication process) has decreased.

Static Random Access Memory (SRAM) is commonly used in integrated circuits. SRAM cells have the advantage of being able to store data with no need to refresh. With increasingly demanding requirements on the speed of integrated circuits, read and write speeds of SRAM cells have become critical. Therefore, it is important to provide density and speed for the SRAM as the cell size continues to be reduced.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIG. 1 is a block diagram of a memory cell, in accordance with some embodiments of the disclosure.

FIG. 2 is a semiconductor device, in accordance with some embodiments of the disclosure.

FIGS. 3A and 3B are cross-sectional views of a plurality of layers in the semiconductor device of FIG. 2, in accordance with some embodiments of the disclosure.

FIG. 4A illustrates a layout of a semiconductor structure of the memory cell in the semiconductor device, in accordance with some embodiments of the disclosure.

FIG. 4B illustrates the features beneath and within the lowest metal layer in the layout of the memory cell of FIG. 4A, in accordance with some embodiments of the disclosure.

FIG. 4C illustrates the features of the interconnect structure of the metal layers in the layout of the memory cell of FIG. 4A, in accordance with some embodiments of the disclosure.

FIG. 5A illustrates a layout of a semiconductor structure of the memory cell in the semiconductor device, in accordance with some embodiments of the disclosure.

FIG. 5B illustrates the features beneath and within the lowest metal layer in the layout of the memory cell of FIG. 5A, in accordance with some embodiments of the disclosure.

FIG. 5C illustrates the features of the interconnect structure of the metal layers in the layout of the memory cell of FIG. 5A, in accordance with some embodiments of the disclosure.

FIG. 6A illustrates a layout of a semiconductor structure of the memory cell in the semiconductor device, in accordance with some embodiments of the disclosure.

FIG. 6B illustrates the features beneath and within the lowest metal layer in the layout of the memory cell of FIG. 6A, in accordance with some embodiments of the disclosure.

FIG. 6C illustrates the features of the interconnect structure of the metal layers in the layout of the memory cell of FIG. 6A, in accordance with some embodiments of the disclosure.

FIG. 7A illustrates a layout of a semiconductor structure of the memory cell in the semiconductor device, in accordance with some embodiments of the disclosure.

FIG. 7B illustrates the features beneath and within the lowest metal layer in the layout of the memory cell of FIG. 7A, in accordance with some embodiments of the disclosure.

FIG. 7C illustrates the features of the interconnect structure of the metal layers in the layout of the memory cell of FIG. 7A, in accordance with some embodiments of the disclosure.

FIG. 8A illustrates a layout of a semiconductor structure of the memory cell in the semiconductor device, in accordance with some embodiments of the disclosure.

FIG. 8B illustrates the features beneath and within the lowest metal layer in the layout of the memory cell of FIG. 8A, in accordance with some embodiments of the disclosure.

FIG. 8C illustrates the features of the interconnect structure of the metal layers in the layout of the memory cell of FIG. 8A, in accordance with some embodiments of the disclosure.

### DETAILED DESCRIPTION

The following disclosure provides many different embodiments, or examples, for implementing different features of the provided subject matter. Specific examples of components and arrangements are described to simplify the disclosure. These are, of course, merely examples and are not intended to be limiting. For example, the formation of a first feature over or on a second feature in the description that follows may include embodiments in which the first and second features are formed in direct contact, and may also include embodiments in which additional features may be formed therebetween. In addition, the present disclosure may repeat reference numerals and/or letters in the various examples. This repetition is for the purpose of simplicity and clarity and does not in itself dictate a relationship between the various embodiments and/or configurations discussed.

While embodiments of the present disclosure are discussed in detail, it should be appreciated that the present disclosure provides many applicable inventive concepts that can be embodied in a wide variety of specific contexts. The specific embodiments discussed are merely illustrative and do not limit the scope of the disclosure.

Further, spatially relative terms, such as “beneath,” “below,” “above,” “upper,” “lower,” “left,” “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

Various semiconductor structures in integrated circuits (ICs) are provided in accordance with various exemplary embodiments. Some variations of some embodiments are discussed. Throughout the various views and illustrative embodiments, like reference numbers are used to designate like elements.

According to the embodiments of the present disclosure, the bit line and word line configuration provides lower metal resistor-capacitor delay for cell speed improvement as well as scaling capability. The bit lines of SRAM are disposed in the lowest metallization layer to reduce bit-line capacitance, and the VSS lines and word lines are disposed in the higher metallization layer. The configuration allows the bit lines to be wider, decreases the metal tracks in SRAM cells, and avoids IR drop issue in the bit lines and VSS conductors, thereby achieving both high-density and high-speed product requirements.

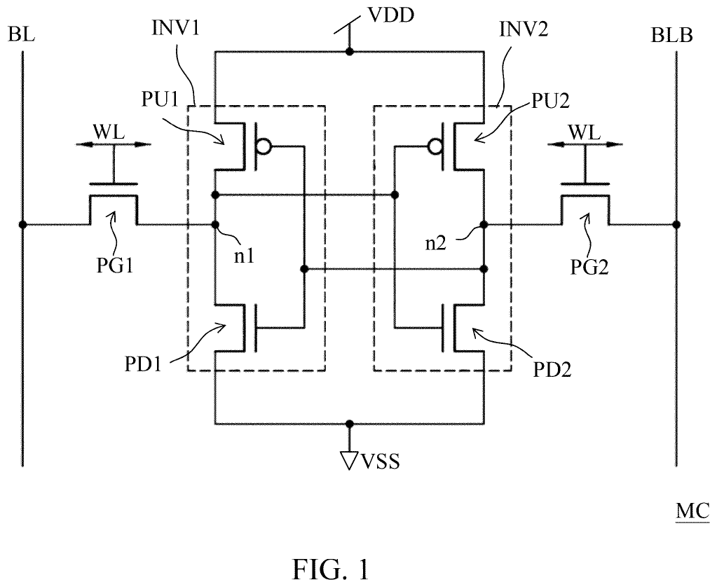

FIG. 1 is a block diagram of a memory cell MC, in accordance with some embodiments of the disclosure. In this embodiment, the memory cell MC is a single-port static random access memory (SRAM) bit cell. A memory array formed by the memory cells MC in rows and columns can be implemented in an integrated circuit (IC), and can be accessed by a controller. The controller may be implemented in the same or another IC.

The memory cell MC includes a pair of inverters INV1 and INV2 cross-coupled between the nodes (or storage nodes) n1 and n2, forming a latch, a pass-gate transistor PG1 coupled between a bit line BL and node n1, and a pass-gate transistor PG2 coupled between a complementary bit line BLB and node n2. The complementary bit line BLB is complementary to the bit line BL. The gates of the pass-gate transistors PG1 and PG2 are coupled to the same word-line WL. In some embodiments, the pass-gate transistors PG1 and PG2 are NMOS transistors.

The inverter INV1 includes a pull-up transistor PU1 and a pull-down transistor PD1. The pull-up transistor PU1 is a PMOS transistor, and the pull-down transistor PD1 is an NMOS transistor. The drains of the pull-up transistor PU1 and the pull-down transistor PD1 are coupled to the node n1 connected to the pass-gate transistor PG1. The gates of the pull-up transistor PU1 and the pull-down transistor PD1 are coupled to the node n2 connected to the pass-gate transistor PG2. Furthermore, the source of the pull-up transistor PU1 is coupled to the positive power supply node VDD, and the source of the pull-down transistor PD1 is coupled to a ground VSS.

Similarly, the inverter INV2 includes a pull-up transistor PU2 and a pull-down transistor PD2. The pull-up transistor PU2 is a PMOS transistor, and the pull-down transistor PD2 is an NMOS transistor. The drains of the pull-up transistor PU2 and the pull-down transistor PD2 are coupled to the node n2 connected to the pass-gate transistor PG2. The gates of the pull-up transistor PU2 and the pull-down transistor PD2 are coupled to the node n1 connected to the pass gate transistor PG1. Furthermore, the source of the pull-up transistor PU2 is coupled to a node of the positive power supply voltage VDD, and the source of the pull-down transistor PD2 is coupled to the ground VSS.

In some embodiments, the pass-gate transistors PG1 and PG2, the pull-up transistors PU1 and PU2, and the pull-down transistors PD1 and PD2 of the memory cell MC are selected from a group consisting of a finFET structure, a vertical gate all around (GAA), a horizontal GAA, fork-sheet structure, a nano wire, a nano sheet, or a combination thereof.

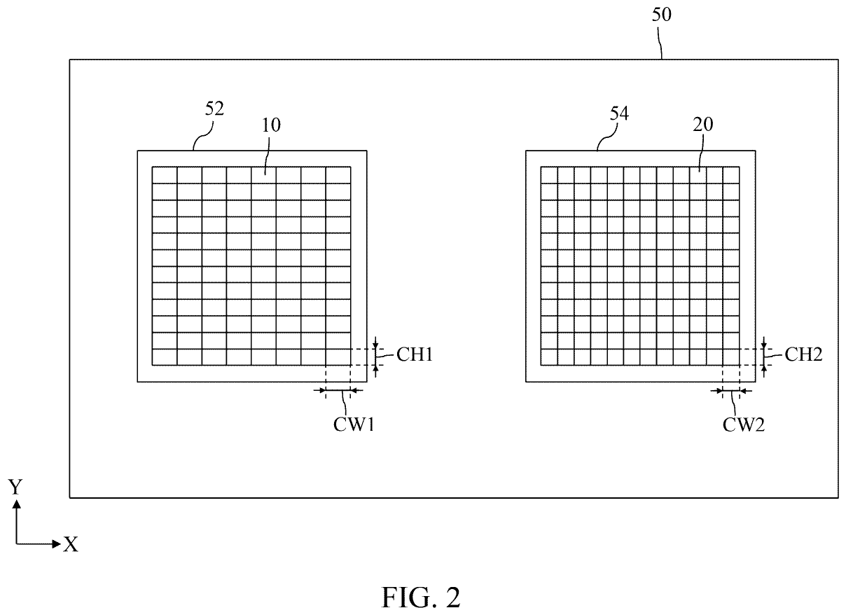

FIG. 2 is a semiconductor device 50, in accordance with some embodiments of the disclosure. The semiconductor device 50 can be, e.g., a microprocessor, an application specific integrated circuit (ASIC), a field programmable gate array (FPGA), a digital signal processor (DSP), or a portion thereof, that includes various passive and active microelectronic devices such as resistors, capacitors, inductors, diodes, p-type field effect transistors (PFETs), n-type field effect transistors (NFETs), FinFET, GAA transistors (such as nanosheet FETs or nanowire FETs), other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, memory devices, other suitable components, or combinations thereof. The exact functionality of the semiconductor device 50 is not a limitation to the provided subject matter.

In the embodiment of FIG. 2, the semiconductor device 50 includes a first SRAM 52 and a second SRAM 54. The first SRAM 52 includes multiple memory cells 10 arranged in rows and columns of a first memory array, and the second SRAM 54 includes multiple memory cells 20 arranged in rows and columns of a second memory array. The first memory array is separated from the second memory array. The number of the memory cells 10 and the number of the memory cells 20 are used as an example, and not limit the disclosure. In order to simplify the description, the peripheral circuits for address decoding and read/write operations of the first and second arrays are omitted. The memory cells 10 and 20 are the single-port SRAM bit cells MC with the same circuit configuration shown in FIG. 1 but different sizes and layouts. In some embodiments, the first SRAM 52 formed by the memory cells 10 is used in the circuits for high speed application, and the second SRAM 54 formed by the memory cells 20 is used in the circuits for high density and larger array.

In the embodiment of FIG. 2, the memory cell 10 has a width CW1 along the X-axis and a height CH1 along the Y-axis, and the memory cell 20 has a width CW2 along the X-axis and a height CH2 along the Y-axis. In some embodiments, the height CH1 is equal to the height CH2, and the width CW2 is less than the width CW1. In some embodiments, a ratio of the width CW1 to the height CH1 can be in a range from about 2 to 3, i.e.,

$$2 \leq \frac{CW 1}{CH 1} \leq 3 .$$

In some embodiments, a ratio of the width CW2 to the height CH2 can be in a range from about 1.8 to 2.5, i.e.

$$1.8 \leq \frac{CW 2}{CH 2} \leq 2.5 .$$

In some embodiments, a ratio of the width CW1 to the width CW2 can be in a range from about 1.1 to 1.3, i.e.,

$$1.1 \leq \frac{CW 1}{CW 2} \leq 1.3 .$$

In some embodiments, the memory cells 10 and 20 may include other types of memory cells, such as two port (TP) SRAM cell.

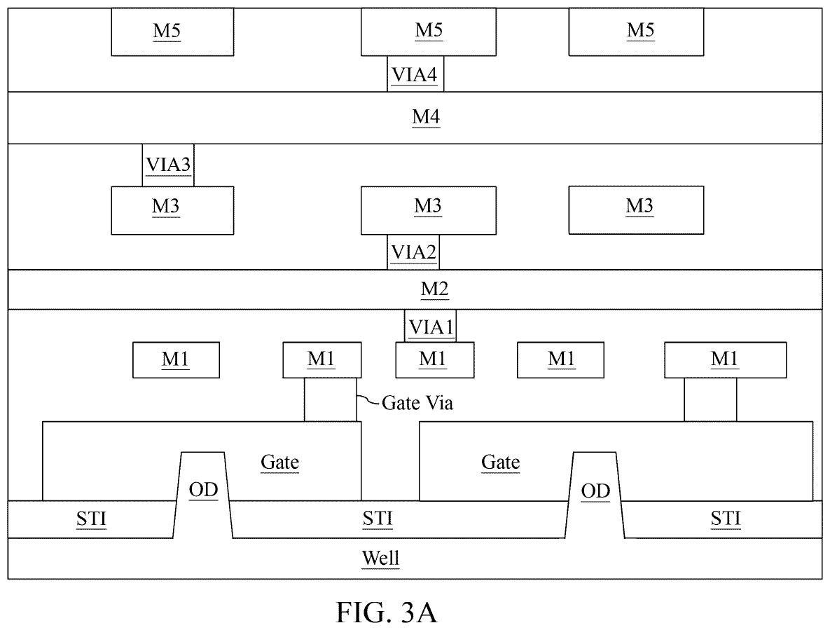

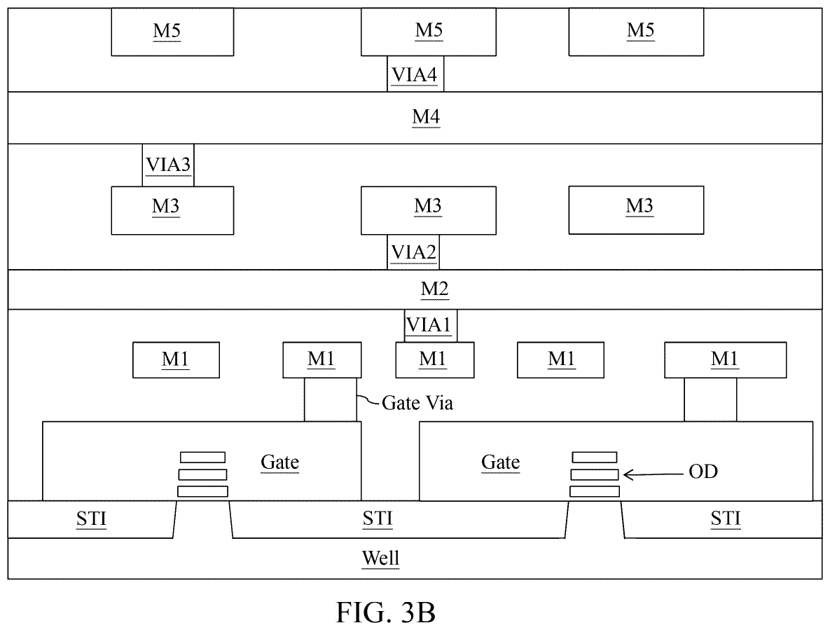

FIGS. 3A and 3B are cross-sectional views of a plurality of layers in the semiconductor device 50 of FIG. 2, in accordance with some embodiments of the disclosure. The configuration of FIG. 3A is similar to the configuration of FIG. 3B. The difference in FIGS. 3A and 3B is that FIG. 3A shows the semiconductor device 50 with FinFETs, and FIG. 3B shows the semiconductor device 50 with GAA transistors. Referring to FIGS. 3A and 3B collectively, the layers of the semiconductor device 50 are formed on a semiconductor chip or wafer. It is noted that FIGS. 3A and 3B are schematically illustrated to show various levels of interconnect structure and transistors, and may not reflect the actual cross-sectional view of memory cells. In accordance with some embodiments, the interconnect structure includes metal layers M1, M2, M3, M4 and M5, with metal layer M1 being the bottommost metal layer in the respective die/wafer. The interconnect structure further includes active regions (also referred to as oxide diffusion or definition (OD) regions), gate vias, and vias VIA1, VIA2, VIA3 and VIA4. Each of the illustrated metal layers includes a plurality of metal features formed therein, with one or more dielectric layers surrounding the metal features. In some embodiments, the one or more dielectric layers including dielectric materials, such as tetraethylorthosilicate (TEOS) oxide, undoped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or a combination thereof.

The metal features that are at the same metal level may have top surfaces substantially level to each other, bottom surfaces substantially level to each other, and may be formed simultaneously. The gate vias may include gate contacts (also referred to as contact plugs) for connecting to the gate electrodes of transistors (such as the transistors in the memory cell MC of FIG. 1) to overlying features such as the metal features in the metal layer M1, and source/drain contacts for connecting the source/drain regions of transistors to the overlying metal features.

The materials of the source/drain contacts, the vias (or connecting features) and the metal lines are selected from a group consisting of titanium (Ti), titanium nitride (TiN), tantalum (Ta), tantalum nitride (TaN), titanium aluminum nitride (TiAlN), tungsten nitride (WN), tungsten (W), cobalt (Co), molybdenum (Mo), ruthenium (Ru), platinum (Pt), aluminum (Al), copper (Cu), other conductive materials, or a combination thereof.

In some embodiments, the ODs are defined by the shallow trench isolation (STI) regions and include the semiconductor fins protruding the SIT, as shown in FIG. 3A. In some embodiments, the ODs are formed by the nanostructures formed on the substrate or well region, as shown in FIG. 3B. In some embodiments, the nanostructures may also be referred to as channels, channel layers, nanosheets, or nanowires. The nanostructures may include a semiconductor material, such as silicon, germanium, silicon carbide, silicon phosphide, gallium arsenide, gallium phosphide, indium phosphide, indium arsenide, and/or indium antimonide, silicon germanium (SiGe), SiPC, GaAsP, AlInAs, AlGaAs, GaInAs, GaInP, and/or GaInAsP. In some embodiments, the nanostructures include silicon for N-type GAA transistors. In other embodiments, the nanostructures include silicon germanium for P-type GAA transistors. In some embodiments, the nanostructures are all made of silicon, and the type of GAA transistors depend on work function metal layer wrapping around the nanostructures.

The nanostructure transistor (e.g. nanosheet transistor, nanowire transistor, multi-bridge channel, nano-ribbon FET, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

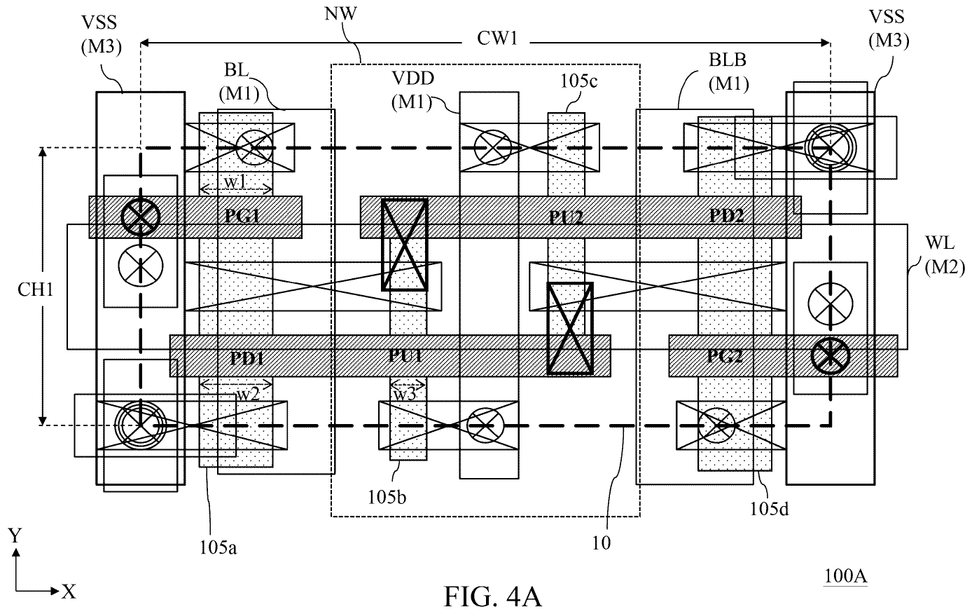

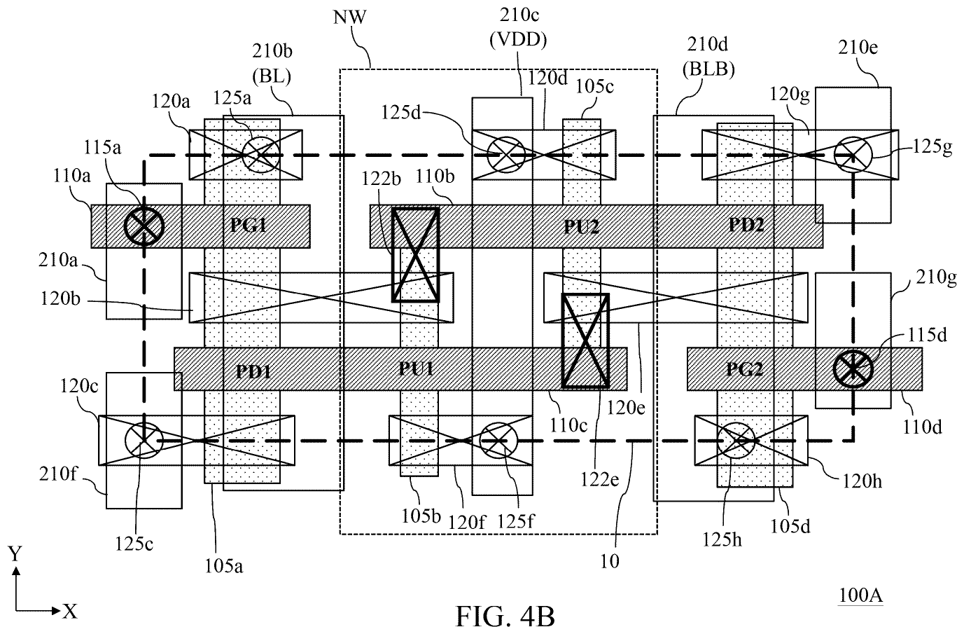

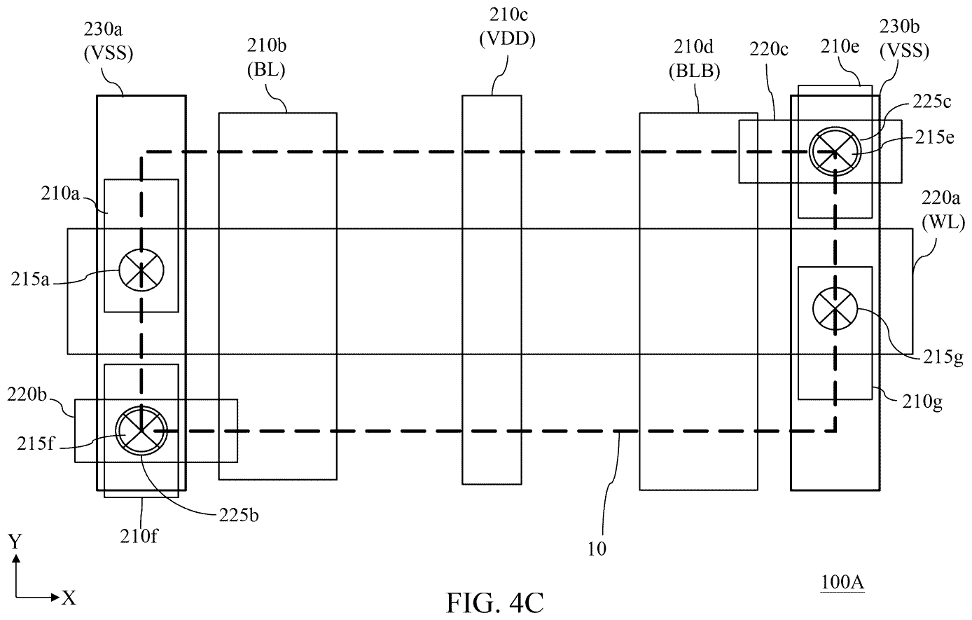

FIG. 4A illustrates a layout of a semiconductor structure 100A of the memory cell 10 in the semiconductor device 50, in accordance with some embodiments of the disclosure. FIG. 4B illustrates the features beneath and within the lowest metal layer M1 and FIG. 4C illustrates the features of the interconnect structure of the metal layers in the layout of the memory cell 10 of FIG. 4A, in accordance with some embodiments of the disclosure. In this embodiment, the memory cell 10 is the single-port SRAM bit cell MC shown in FIG. 1. Furthermore, an outer boundary of the memory cell 10 is illustrated using dashed lines.

In the semiconductor structure 100A, the memory cell 10 has a rectangular region with the width CW1 along the X-axis and the height CH1 along the Y-axis, and the height CH1 is shorter than the width CW1. The pass-gate transistor PG1 and the pull-down transistor PD1 are formed in an active region 105a with the widths w1 and w2, respectively, and the pull-up transistor PU1 is formed in an active region 105b with a width w3. Furthermore, the pull-up transistor PU2 is formed in an active region 105c with the width w3, and the pass-gate transistor PG2 and the pull-down transistor PD2 are formed in an active region 105d with the widths w1 and w2, respectively. The active regions 105a through 105d extend along the Y-axis. In some embodiments, the active regions 105a and 105d are formed in a P-type well region, and the active regions 105b and 105c are formed in an N-type well region NW. In some embodiments, the width w1 is equal to or less the width w2, and the width w3 is less than the width w2. In some embodiments, a ratio of the width w2 to the width w1 can be in a range from about 1 to 1.4, i.e.,

$$1 \leq \frac{w 2}{w 1} \leq 1.4 .$$

In some embodiments, a ratio of the width w2 to the width w3 can be in a range from about 1.05 to 4, i.e.,

$$1.05 \leq \frac{w 2}{w 3} \leq 4 .$$

The active region 105b is disposed between the active regions 105a and 105c, and the active region 105c is disposed between the active regions 105b and 105d. In some embodiments, the active regions 105a and 105d have the same width along the Y-axis, and a width of the active regions 105b and 105c have the same width along the Y-axis. In some embodiments, the active regions 105a through 105d have the same pitch. In some embodiments, each of the active regions 105a through 105d is formed by semiconductor fin formed on the substrate. In some embodiments, each of the active regions 105a through 105d is formed by the stacked nanostructures formed on the substrate.

The source/drain contacts 120a through 120h and the gate structures 110a through 110d extend along the X-axis. The source/drain contacts 120a through 120h are the longer contacts each having a rectangular shape in the layout view, and disposed over the source/drain regions of the transistors in the memory cell 10. The source/drain contacts 120a through 120h are configured to connect the source/drain regions of the transistors in the memory cell 10. Source/drain region(s) may refer to a source or a drain, individually or collectively dependent upon the context. In some embodiments, the active regions 105a through 105d extend along the X-axis, and the source/drain contacts 120a through 120h and the gate structures 110a through 110d extend along the Y-axis.

The gate structure 110a forms the pass-gate transistor PG1 with the active region 105a. The gate structure 110b forms the pull-up transistor PD1 with the active region 105a and forms the pull-up transistor PU1 with the active region 105b. The gate structure 110c forms the pull-up transistor PU2 with the active region 105c and forms the pull-down transistor PD2 with the active region 105d. The gate structure 110d forms the pass-gate transistor PG2 with the active region 105d. In some embodiments, the gate structures 110a and 110d are shared with the adjacent memory cells 10 in adjacent columns.

The gate structure 110a is electrically connected to the metal line 210a through the gate via 115a. The metal line 210a functions as a landing pad (or a landing line) of the word line WL, and is configured to electrically connect to the metal line 220a through the via 215a (e.g., the via VIA1 of FIGS. 3A and 3B). The gate structure 110b is electrically connected to the source/drain contact 120e through the butt contact 122e, and the butt contact 122e functions as a local connection of the node n2 in the memory cell 10. The gate structure 110c is electrically connected to the source/drain contact 120b through the butt contact 122b. The butt contact 122b functions as a local connection of the node n1 in the memory cell 10. The gate structure 110d is electrically connected to the metal line 210g through the gate via 115d. The metal line 210g functions as a landing pad (or a landing line) of the word line WL for the memory cell 10, and is configured to electrically connect to the metal line 220a through the via 215g. The butt contacts 122b and 112e are gate-to-drain contacts and extend along the Y-axis. In some embodiments, the butt contacts 122b and 112e are formed simultaneously with the source/drain contacts 120a through 120h in a same procedure that includes dielectric deposition, patterning and metal deposition.

The source/drain contact 120a overlaps the active region 105a and corresponds to one source/drain feature of the pass-gate transistor PG1. The source/drain contact 120a is electrically connected to the metal line 210b through the via 125a. The metal line 210b functions as the bit line BL of the memory cell 10. The metal line 210b is shared with the adjacent memory cells 10 in adjacent row. The source/drain contact 120b overlaps the active regions 105a and 105b and corresponds to another source/drain feature of the pass-gate transistor PG1, and the drain features of the pull-up transistor PU1 and the pull-down transistor PD1. In other words, the source/drain contact 120b is shared by the pass-gate transistor PG1, the pull-up transistor PU1 and the pull-down transistor PD1. The source/drain contact 120b is electrically connected to the butt contact 122b to connect to the gate structure 110c.

The source/drain contact 120c overlaps the active region 105a and corresponds to the source feature of the pull-down transistor PD1. The source/drain contact 120c is electrically connected to the metal line 210f through the via 125c. The metal line 210f functions as a landing pad (or a landing line) of the VSS line (or VSS conductor) for the memory cell 10, and is configured to electrically connect to the metal line 230a through the via 215f (e.g., the via VIA1), the metal line 220b, and the via 225b (e.g., the via VIA2) in sequence. The source/drain contact 120f overlaps the active region 105b and corresponds to the source feature of the pull-up transistor PU1. The source/drain contact 120f is electrically connected to the metal line 210c through the via 125f. The metal line 210c functions as the VDD line (or VDD conductor) for the memory cell 10.

The source/drain contact 120h overlaps the active region 105d and corresponds to one source/drain feature of the pass-gate transistor PG2. The source/drain contact 120h is electrically connected to the metal line 210d through the via 125h. The metal line 210d functions as the complementary bit line BLB of the memory cell 10. The metal line 210d is shared with the adjacent memory cells 10 in adjacent row. The source/drain contact 120e overlaps the active regions 105c and 105d and corresponds to another source/drain feature of the pass-gate transistor PG2, and the drain features of the pull-up transistor PU2 and the pull-down transistor PD2. In other words, the source/drain contact 120e is shared by the pass-gate transistor PG2, the pull-up transistor PU2 and the pull-down transistor PD2. The source/drain contact 120e is electrically connected to the butt contact 112e to connect to the gate structure 110b.

The source/drain contact 120g overlaps the active region 105d and corresponds to the source feature of the pull-down transistor PD2. The source/drain contact 120g is electrically connected to the metal line 210e through the via 125g. The metal line 210e functions as a landing pad (or a landing line) of the VSS line (or VSS conductor) for the memory cell 10, and is configured to electrically connect to the metal line 230b through the via 215e, the metal line 220c, and the via 225c in sequence. The source/drain contact 120d overlaps the active region 105c and corresponds to the source feature of the pull-up transistor PU2. The source/drain contact 120d is electrically connected to the metal line 210c through the via 125d. As described above, the metal line 210c functions as the VDD line for the memory cell 10. The metal line 210c is shared with the memory cells 10 in the same column of the array.

In the semiconductor structure 100A, the metal lines 210a through 210g are formed in the metal layer M1 and extend along the Y-axis, i.e., the metal lines 210a through 210g are parallel to the active regions 105a through 105d. The metal lines 210b, 210c and 210d function as the bit line BL, the VDD line, and the complementary bit line BLB of the memory cell 10, respectively. Furthermore, the bit line BL and the complementary bit line BLB are wider than the VDD line.

The metal lines 220a through 220c are formed in the metal layer M2 and extend along the X-axis, i.e., the metal lines 220a through 220c are parallel to the gate structures 110a through 110d. The metal line 220a functions as the word line WL of the memory cell 10. The metal line 220a is shared with the memory cells 10 in the same row of the array.

The metal lines 230a and 230b are formed in the metal layer M3 and extend along the Y-axis, i.e., the metal lines 230a and 230b are parallel to the active regions 105a through 105d. Each of the metal lines 230a and 230b functions as the VSS line of the memory cell 10. The metal lines 230a and 230b are shared with the memory cells 10 in the same column of the array. In some embodiments, the bit line BL and the complementary bit line BLB are wider than the VSS lines, and the VSS lines are wider than the VDD line.

In the semiconductor structure 100A of FIGS. 4A-4C, for the memory cell 10, the bit line BL, the VDD line, and the complementary bit line BLB are disposed in the metal layer M1. Furthermore, the word line WL is disposed in the metal layer M2, and the VSS lines are disposed in the metal layer M3. The configuration allows the bit line BL to be wider, decreases the metal tracks in each metal layer, and avoids IR drop issue in the bit line BL and the VSS conductors of the VSS line.

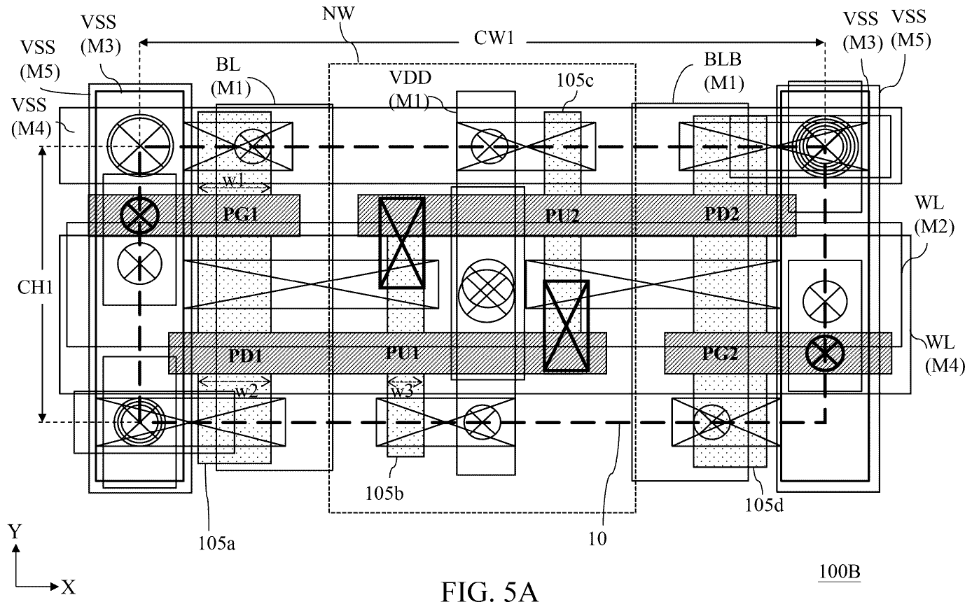

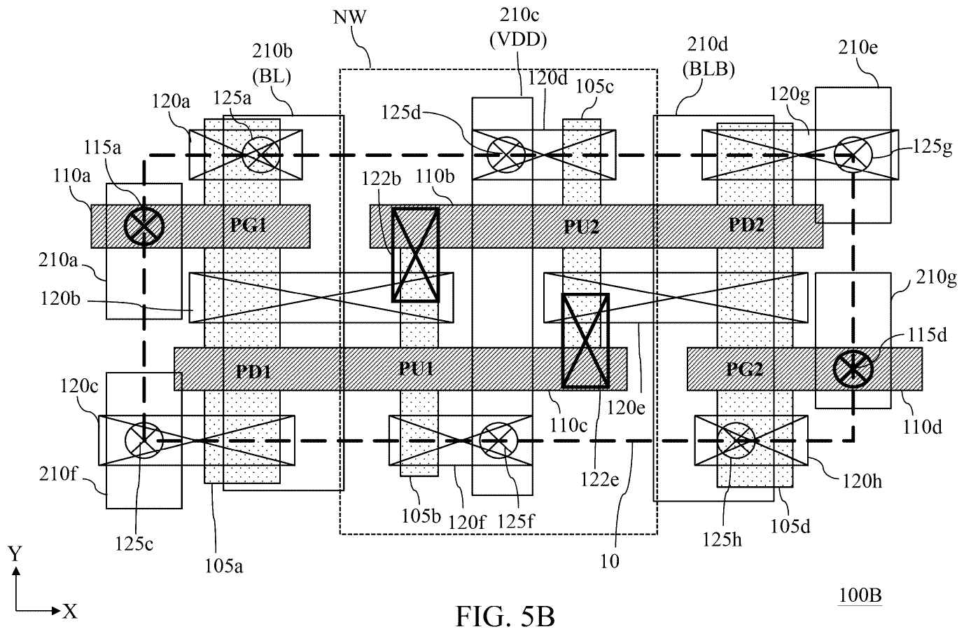

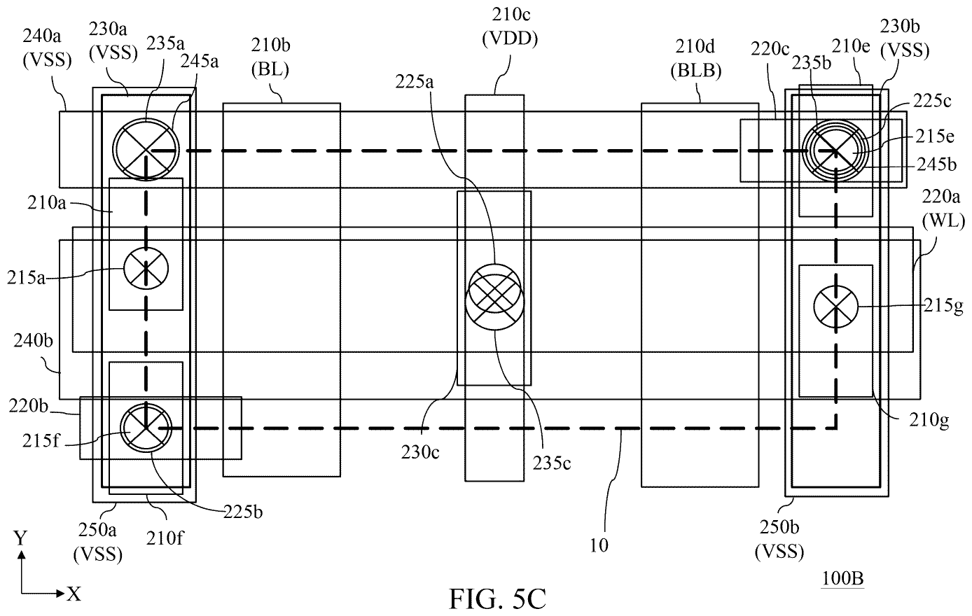

FIG. 5A illustrates a layout of a semiconductor structure 100B of the memory cell 10 in the semiconductor device 50, in accordance with some embodiments of the disclosure. FIG. 5B illustrates the features beneath and within the lowest metal layer M1 and FIG. 5C illustrates the features of the interconnect structure of the metal layers in the layout of FIG. 5A, in accordance with some embodiments of the disclosure. In this embodiment, the memory cell 10 is the single-port SRAM bit cell MC shown in FIG. 1. Furthermore, an outer boundary of the memory cell 10 is illustrated using dashed lines.

The configuration of the semiconductor structure 100A of FIGS. 4A through 4C is similar to the configuration of the semiconductor structure 100B of FIGS. 5A through 5C. The different between the semiconductor structures 100A and 100B is that the semiconductor structure 100B provides more word line WL and more VSS lines for the memory cell 10.

In the metal layer M3, the semiconductor structure 100B further includes the metal line 230c The metal line 230c is coupled to the metal line 220a through the via 225a. Furthermore, the metal line 230c is further coupled to the metal line 240b through the via 235c (e.g., the via VIA3 of FIGS. 3A and 3B). The metal line 240b functions as the word line WL of the memory cell 20, and overlaps the word line WL (i.e., the metal line 220a) in the metal layer M2. The metal line 240b is shared with the memory cells 10 in the same row of the array.

The metal lines 240a and 240b are formed in the metal layer M4 and extend along the X-axis, i.e., the metal lines 240a and 240b are parallel to the gate structures 110a through 110d. The metal line 240a is coupled to the metal line 230a through the via 235 and to the metal line 230b through the via 235b. The metal line 240a is narrower than the metal line 240b. The metal line 240a is further coupled to the metal lines 250a and 250b in the metal layer M5 through the vias 245a and 245b, respectively. The metal line 240a functions as the VSS line of the memory cell 10. The metal line 240a is shared with the memory cells 10 in the same row of the array.

The metal lines 250a and 250b are formed in the metal layer M5 and extend along the Y-axis, i.e., the metal lines 250a and 250b are parallel to the active regions 105a through 105d. The metal line 250a functions as the VSS line of the memory cell 10, and overlaps the VSS line (i.e., the metal line 230a) in the metal layer M3. Similarly, the metal line 250b functions as the VSS line of the memory cell 10, and overlaps the VSS line (i.e., the metal line 230b) in the metal layer M3. The metal lines 250a and 250b are shared with the memory cells 10 in the same column of the array.

In the semiconductor structure 100B of FIGS. 5A-5C, for the memory cell 10, the bit line BL, the VDD line, and the complementary bit line BLB are disposed in the metal layer M1. Furthermore, the word lines WL are disposed in the metal layers M2 and M4 and are electrically connected in parallel, i.e., the double word lines, thereby decreasing the resistance of the word line WL and benefiting array speed. Furthermore, the VSS lines are disposed in the metal layers M3 through M5 and are electrically connect in parallel, thereby decreasing the resistance of the VSS line. The configuration allows the bit line BL to be wider, decreases the metal tracks in each metal layer, and avoids IR drop issue in the bit line BL and the VSS conductors of the VSS line.

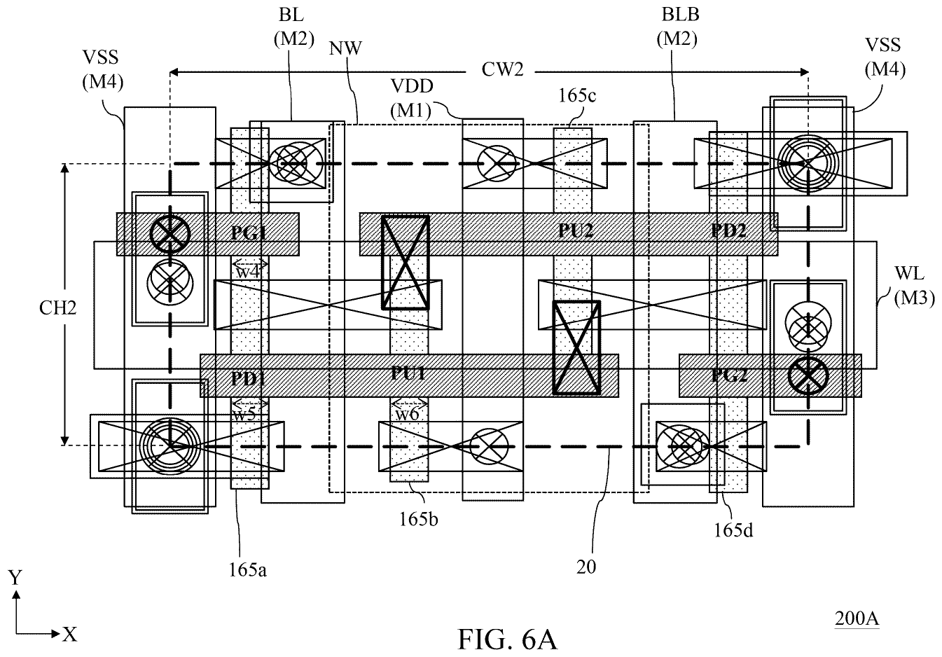

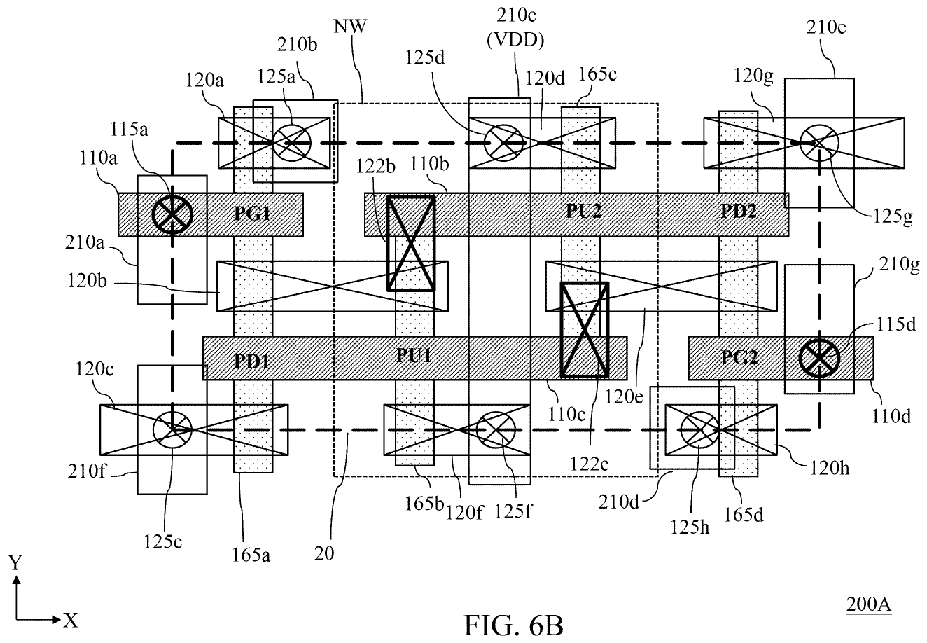

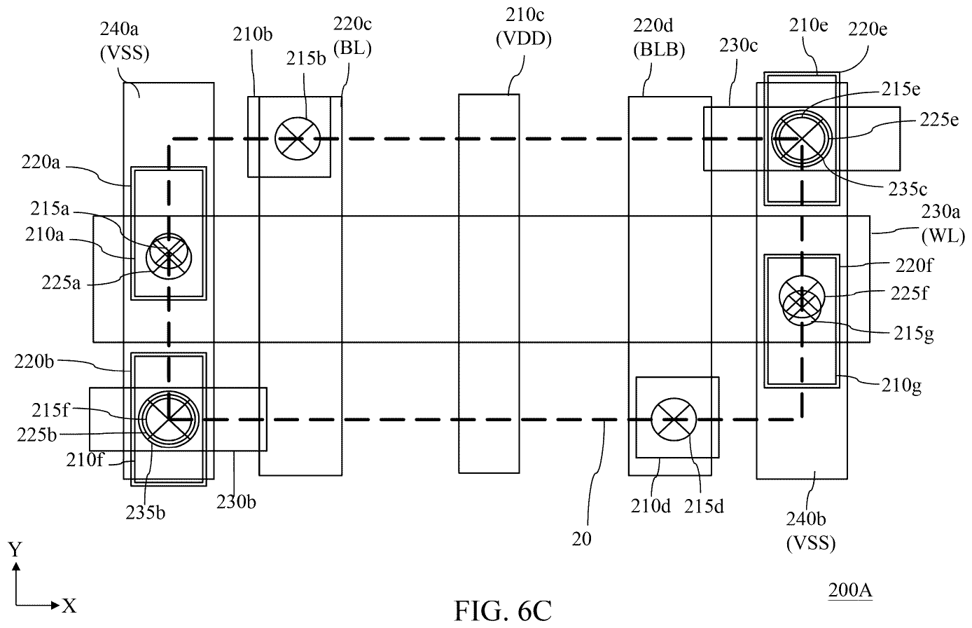

FIG. 6A illustrates a layout of a semiconductor structure 200A of the memory cell 20 in the semiconductor device 50, in accordance with some embodiments of the disclosure. FIG. 6B illustrates the features beneath and within the lowest metal layer M1 and FIG. 6C illustrates the features of the interconnect structure of the metal layers in the layout of FIG. 6A, in accordance with some embodiments of the disclosure. In this embodiment, the memory cell 20 is the single-port SRAM bit cell MC shown in FIG. 1. Furthermore, an outer boundary of the memory cell 20 is illustrated using dashed lines.

In the semiconductor structure 200A, the memory cell 20 has a rectangular region with the width CW2 along the X-axis and the height CH2 along the Y-axis, and the height CH2 is shorter than the width CW2. The pass-gate transistor PG1 and the pull-down transistor PD1 are formed in an active region 165a with the widths w4 and w5, respectively, and the pull-up transistor PU1 is formed in an active region 165b with a width w6. Furthermore, the pull-up transistor PU2 is formed in an active region 165c with the width w6, and the pass-gate transistor PG2 and the pull-down transistor PD2 are formed in an active region 165d with the widths w4 and w5, respectively. The active regions 165a through 165d extend along the Y-axis. In some embodiments, the width w4 is equal to or less the width w5, and the width w6 is less than the width w5. In some embodiments, a ratio of the width w5 to the width w4 can be in a range from about 1 to 1.4, i.e.,

$$1 \leq \frac{w 5}{w 4} \leq 1.4 .$$

In some embodiments, a ratio of the width w5 to the width w6 can be in a range from about 1.05 to 4, i.e.,

$$1.05 \leq \frac{w 5}{w 6} \leq 4 .$$

In the back-end-of-line (BEOL) layers including the metal layer M1 and above, the interconnects of the semiconductor structure 100A of FIGS. 4A and 4C are different from the interconnects of the semiconductor structure 200A of FIGS. 6A and 6C. In the front-end-of-line (FEOL) and the mid-end-of-line (MEOL) layers including the layers below the metal layer M1, the configuration of the semiconductor structure 100A of FIGS. 4A and 4B is similar to the configuration of the semiconductor structure 200A of FIGS. 6A and 6B. The difference in the FEOL and MEOL layers between the semiconductor structures 100A and 200A is that the active regions 105a through 105d of the semiconductor structure 100A are wider than the active regions 165a through 165d of the semiconductor structure 200A, thus the width CW1 of the memory cell 10 is greater than the width CW2 of the memory cell 20. Therefore, for the same array area, the density of the memory cells 20 is higher than the density of the memory cells 10. In some embodiments, a ratio of the width w1 to the width w4 can be in a range from about 1.3 to 4, i.e.,

$$1.3 \leq \frac{w 1}{w 4} \leq 4 .$$

In some embodiments, the active regions 105a through 105d of the semiconductor structure 100A are perpendicular to the active regions 165a through 165d of the semiconductor structure 200A.

In the semiconductor structure 200A, the metal lines 210a through 210g are formed in the metal layer M1 and extend along the Y-axis, i.e., the metal lines 210a through 210g are parallel to the active regions 165a through 165d. The metal line 210c functions as the VDD line of the memory cell 20. The metal line 210c is shared with the memory cells 20 in the same column of the array. In some embodiments, the same power supply voltage VDD are applied to the VDD lines of the memory cells 10 and 20. In some embodiments, different power supply voltages VDD are applied to the VDD lines of the memory cells 10 and 20, respectively.

The metal line 210a functions as a landing pad (or a landing line) of the word line WL for the memory cell 20, and is configured to electrically connect to the metal line 230a through the via 215a (e.g., the via VIA1 of FIGS. 3A and 3B), the metal line 220a and the via 225a (e.g., the via VIA2 of FIGS. 3A and 3B) in sequence. Similarly, the metal line 210g functions as a landing pad (or a landing line) of the word line WL, and is configured to electrically connect to the metal line 230a through the via 215g, the metal line 220f and the via 225f in sequence. The metal line 210b functions as a landing pad (or a landing line) of the bit line BL for the memory cell 20, and is configured to electrically connect to the metal line 220c through the via 215b. Similarly, the metal line 210d functions as a landing pad (or a landing line) of the complementary bit line BLB for the memory cell 20, and is configured to electrically connect to the metal line 220d through the via 215d. The metal line 210f functions as a landing pad (or a landing line) of the VSS line (or VSS conductor) for the memory cell 20, and is configured to electrically connect to the metal line 240a through the via 215f, the metal line 220b, the via 225b, the metal line 230b, and the via 235b (e.g., the via VIA3 of FIGS. 3A and 3B) in sequence.

The metal lines 220a through 220f are formed in the metal layer M2 and extend along the Y-axis, i.e., the metal lines 220a through 220f are parallel to the active regions 165a through 165d. The metal line 220c and 220d function as the bit line BL and the complementary bit line BLB of the memory cell 20, respectively. The metal line 220c and 220d are shared with the memory cells 20 in the same column of the array.

The metal lines 230a through 230d are formed in the metal layer M3 and extend along the X-axis, i.e., the metal lines 230a through 230d are parallel to the gate structures 110a through 110d. The metal line 230a functions as the word line WL of the memory cell 20. The metal line 230a is shared with the memory cells 20 in the same row of the array.

The metal lines 240a and 240b are formed in the metal layer M4 and extend along the Y-axis, i.e., the metal lines 240a and 240b are parallel to the active regions 165a through 165d. Each of the metal lines 240a and 240b functions as the VSS line of the memory cell 20. The metal lines 240a and 240b are shared with the memory cells 20 in the same column of the array. In some embodiments, the bit line BL, the complementary bit line BLB, and the VSS lines are wider than the VDD line.

In the semiconductor structure 200A of FIGS. 6A-6C, for the memory cell 20, the VDD line is disposed in the metal layer M1, and the bit line BL and the complementary bit line BLB are disposed in the metal layer M2. Furthermore, the word line WL is disposed in the metal layer M3, and the VSS lines are disposed in the metal layer M4. The word line WL, the bit line BL, the complementary bit line BLB, and the VSS lines of the memory cell 20 in the semiconductor structure 200A are disposed on different metal layers than those of the memory cell 10 in the semiconductor structure 100A. Compared with the semiconductor structure 100A of the memory cell 10, the bit line BL and the complementary bit line BLB in the semiconductor structure 200A are relocated to the metal layer M2. The metal layer M2 offers a larger area for routing compared to the metal layer M1, allowing for an increase in line width to accommodate a larger array, such as more columns and rows. The configuration allows the bit line BL to be wider, decreases the metal tracks in each metal layer, and avoids IR drop issue in the bit line BL and the VSS conductors of the VSS line.

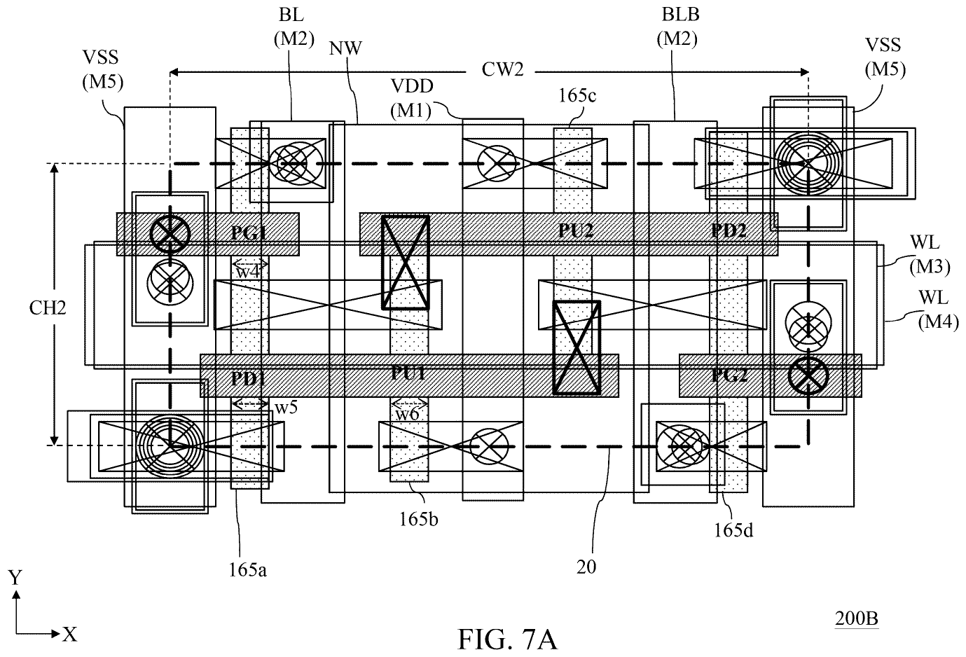

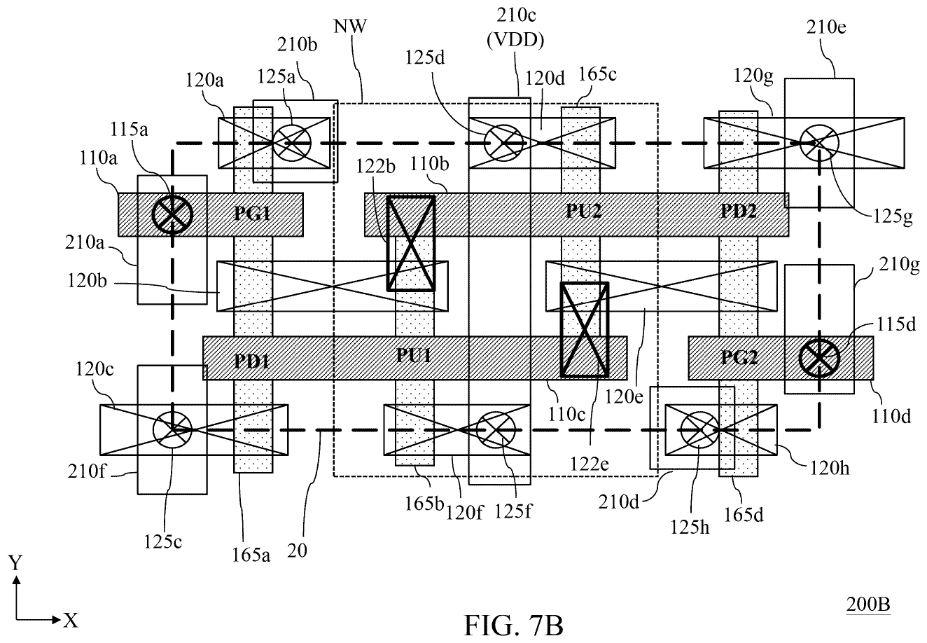

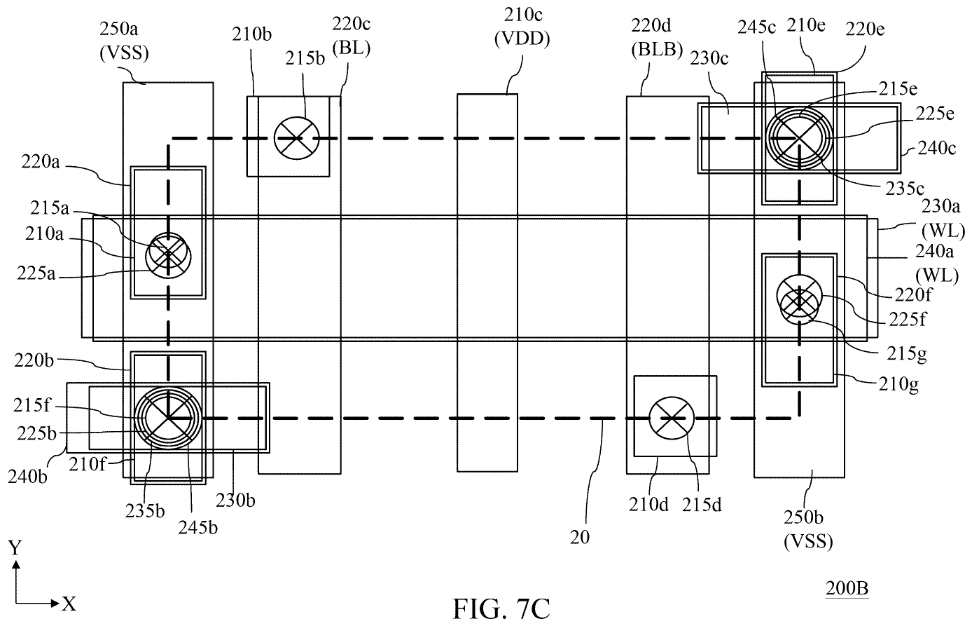

FIG. 7A illustrates a layout of a semiconductor structure 200B of the memory cell 20 in the semiconductor device 50, in accordance with some embodiments of the disclosure. FIG. 7B illustrates the features beneath and within the lowest metal layer M1 and FIG. 7C illustrates the features of the interconnect structure of the metal layers in the layout of FIG. 7A, in accordance with some embodiments of the disclosure. In this embodiment, the memory cell 20 is the single-port SRAM bit cell MC shown in FIG. 1. Furthermore, an outer boundary of the memory cell 20 is illustrated using dashed lines.

The configuration of the semiconductor structure 200B of FIGS. 7A through 7C is similar to the configuration of the semiconductor structure 200A of FIGS. 6A through 6C. The different between the semiconductor structures 200A and 200B is that the semiconductor structure 200B provides more word line WL for the memory cell 20.

The metal lines 240a through 240c are formed in the metal layer M4 and extend along the X-axis, i.e., the metal lines 240a through 240c are parallel to the gate structures 110a through 110d. The metal line 240a functions as the word line WL of the memory cell 20. The metal line 240a is shared with the memory cells 20 in the same row of the array. The metal line 240b functions as a landing pad (or a landing line) of the VSS line for the memory cell 20, and is configured to electrically connect to the metal line 250a through the via 245b (e.g., the via VIA4 of FIGS. 3A and 3B). The metal line 240c functions as a landing pad (or a landing line) of the VSS line for the memory cell 20, and is configured to electrically connect to the metal line 250b through the via 245c.

The metal lines 250a and 250b are formed in the metal layer M5 and extend along the Y-axis, i.e., the metal lines 250a and 250b are parallel to the active regions 165a through 165d. Each of the metal lines 250a and 250b functions as the VSS line of the memory cell 20. The metal lines 250a and 250b are shared with the memory cells 20 in the same column of the array.

In the semiconductor structure 200B of FIGS. 7A-7C, for the memory cell 20, the VDD line is disposed in the metal layer M1, and the bit line BL and the complementary bit line BLB are disposed in the metal layer M2. Furthermore, Furthermore, the word lines WL are disposed in the metal layers M3 and M4 and are electrically connected in parallel, thereby decreasing the resistance of the word line WL and benefiting array speed. The VSS lines are disposed in the metal layers M5. A portion of the VSS lines and word lines WL of the memory cell 10 in the semiconductor structure 100B and the memory cell 20 in the semiconductor structure 200B are disposed on the same metal layers (e.g., the metal layers M4 and M5). The configuration allows the bit line BL to be wider, decreases the metal tracks in each metal layer, and avoids IR drop issue in the bit line BL and the VSS conductors of the VSS line.

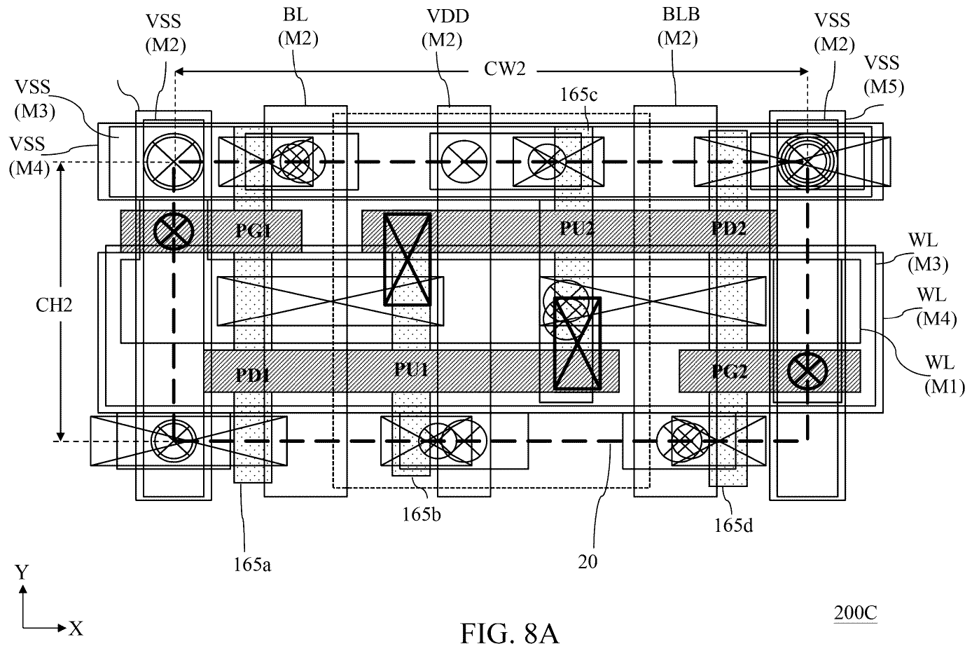

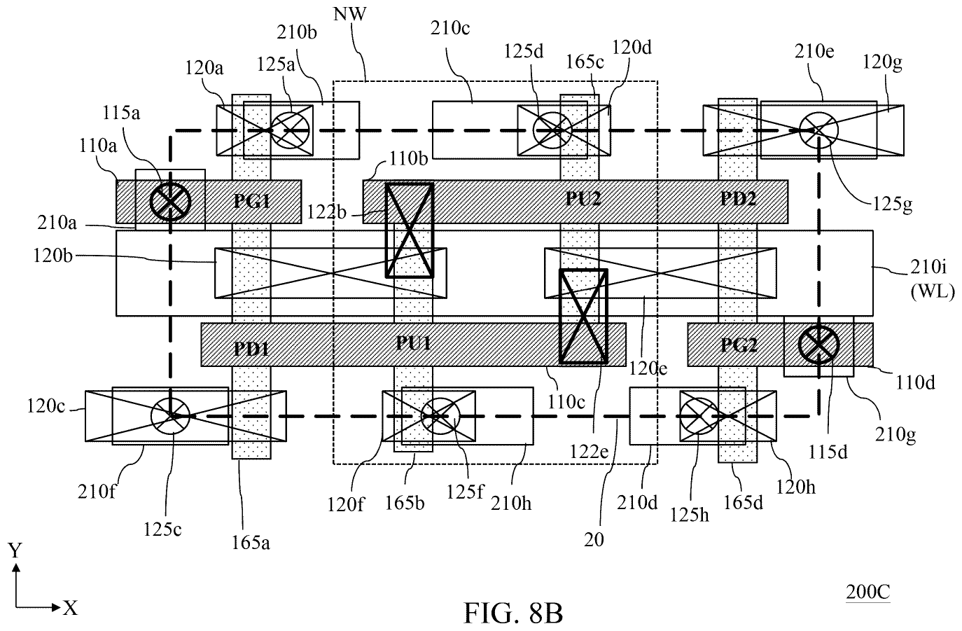

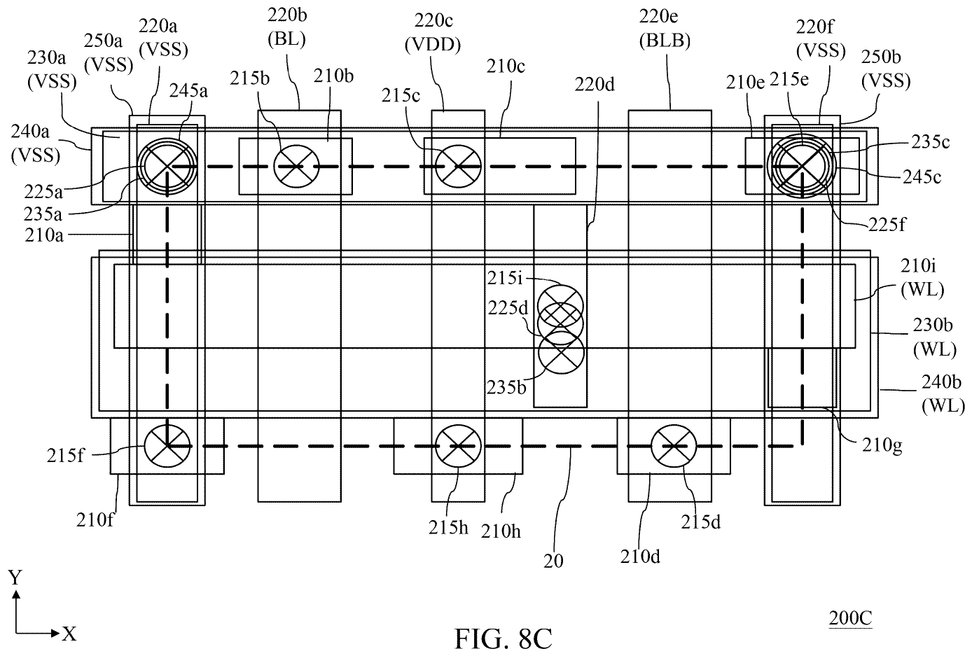

FIG. 8A illustrates a layout of a semiconductor structure 200C of the memory cell 20 in the semiconductor device 50, in accordance with some embodiments of the disclosure. FIG. 8B illustrates the features beneath and within the lowest metal layer M1 and FIG. 8C illustrates the features of the interconnect structure of the metal layers in the layout of FIG. 8A, in accordance with some embodiments of the disclosure. In this embodiment, the memory cell 20 is the single-port SRAM bit cell MC shown in FIG. 1. Furthermore, an outer boundary of the memory cell 20 is illustrated using dashed lines.

The FEOL and MEOL configuration of the semiconductor structure 200C of FIGS. 8A through 8C is similar to the FEOL and MEOL configuration of the semiconductor structure 200A of FIGS. 6A through 6C. The different between the semiconductor structures 200A and 200C is that the semiconductor structure 200C provides more word line WL and more VSS lines for the memory cell 20 in the BEOL layers.

The gate structure 110a is electrically connected to the metal line 210a through the gate via 115a. The gate structure 110d is electrically connected to the metal line 210h through the gate via 115d. The metal lines 210a and 210h contact the metal line 210i in the metal layer M1, and the metal line 210i functions as the word line WL of the memory cell 20. The metal line 210i is shared with the memory cells 10 in the same row of the array. In some embodiments, the metal lines 210a, 210h and 210i are formed by the same processes in the metal layer M1.

The source/drain contact 120a is electrically connected to the metal line 210b through the via 125a. The metal line 210b functions as a landing pad (or a landing line) of the bit line BL of the memory cell 20, and is configured to electrically connect to the metal line 220b through the via 215b (e.g., the via VIA1). The source/drain contact 120c is electrically connected to the metal line 210f through the via 125c. The metal line 210f functions as a landing pad (or a landing line) of the VSS line (or VSS conductor) for the memory cell 20, and is configured to electrically connect to the metal line 220a through the via 215f (e.g., the via VIA1). The source/drain contact 120f is electrically connected to the metal line 210h through the via 125f. The metal line 210c functions as a landing pad (or a landing line) of the VDD line (or VDD conductor), and is configured to electrically connect to the metal line 220e through the via 215d.

The source/drain contact 120g is electrically connected to the metal line 210e through the via 125g. The metal line 210e functions as a landing pad (or a landing line) of the VSS line (or VSS conductor), and is configured to electrically connect to the metal line 220f through the via 215e. The source/drain contact 120d is electrically connected to the metal line 210c through the via 125d. The metal line 210c functions as a landing pad (or a landing line) of the VDD line, and is configured to electrically connect to the metal line 220c through the via 215c.

In the semiconductor structure 200C, the metal lines 210a through 210h are formed in the metal layer M1 and extend along the X-axis, i.e., the metal lines 210a through 210h are parallel to the gate structures 110a through 110d. The metal line 210i functions as the word line WL. The metal line 230i is shared with the memory cells 20 in the same row of the array.

The metal lines 220a through 220f are formed in the metal layer M2 and extend along the Y-axis, i.e., the metal lines 220a through 220f are parallel to the active regions 165a through 165d. Each of the metal lines 220a and 220f functions as the VSS line of the memory cell 20. The metal line 220b and 220d function as the bit line BL and the complementary bit line BLB of the memory cell 20, respectively. The metal line 220c functions as the VDD line. The metal line 220d functions as a landing pad (or a landing line) of the word line WL, and is configured to electrically connect to the metal line 240b through the via 225d (i.e., the via VIA2), the metal line 230b, the via 235b (i.e., the via VIA3) in sequence. The metal lines 220a, 220b, 220c, 220e and 220f are shared with the memory cells 10 in the same column of the array.

The metal lines 230a and 230b are formed in the metal layer M3 and extend along the X-axis, i.e., the metal lines 230a and 230b are parallel to the gate structures 110a through 110d. The metal line 230a functions as the VSS line of the memory cell 20, and is configured to connected to the metal line 250a through the vias 235a and 235c (e.g., the via VIA3), the metal line 240a, and the vias 245a and 245c (e.g., the via VIA4) in sequence. The metal line 230b functions as the word line WL. The metal lines 230a and 230b are shared with the memory cells 20 in the same row of the array.

The metal lines 240a and 240b are formed in the metal layer M4 and extend along the X-axis, i.e., the metal lines 240a and 240b are parallel to the gate structures 110a through 110d. The metal line 240a functions as the VSS line of the memory cell 20. The metal line 240b functions as the word line WL. The metal lines 240a and 240b are shared with the memory cells 20 in the same row of the array.

The metal lines 250a and 250b are formed in the metal layer M5 and extend along the Y-axis, i.e., the metal lines 230a and 230b are parallel to the active regions 165a through 165d. Each of the metal lines 250a and 250b functions as the VSS line of the memory cell 20. The metal lines 250a and 250b are shared with the memory cells 20 in the same column of the array.

In the semiconductor structure 200C of FIGS. 8A-8C, for the memory cell 20, the bit line BL, the VDD line, and the complementary bit line BLB are disposed in the metal layer M2. Furthermore, the word lines WL are disposed in the metal layers M1, M3 and M4 and are electrically connected in parallel, i.e., the triple word lines, thereby decreasing the resistance of the word line WL and benefiting array speed. Furthermore, the VSS lines are disposed in the metal layers M2 through M5 and are electrically connect in parallel, thereby decreasing the resistance of the VSS line. The configuration allows the bit line BL to be wider, decreases the metal tracks in each metal layer, and avoids IR drop issue in the bit line BL and the VSS conductors of the VSS line.

According to some embodiments, a semiconductor device is provided. The semiconductor device includes a first memory cell and a second memory cell. The first memory cell includes a first pass-gate transistor having a first gate structure electrically connected to a first word line extending parallel to the first gate structure, and a source/drain feature electrically connected to a first bit line extending perpendicular to the first gate structure; and a first pull-up transistor having a source electrically connected to a first VDD line extending perpendicular to the first gate structure. The second memory cell includes a second pass-gate transistor having a second gate structure electrically connected to a second word line extending parallel to the second gate structure, and a source/drain feature electrically connected to a second bit line extending perpendicular to the second gate structure; and a second pull-up transistor having a source electrically connected to a second VDD line extending perpendicular to the second gate structure. The first VDD line, the first bit line and the second VDD line are disposed in a first metal layer closest to the first and second gate structures, and the first word line and the second bit line are disposed in a second metal layer over the first metal layer.

According to some embodiments, a semiconductor device is provided. The semiconductor device includes a first memory cell and a second memory cell. The first memory cell includes a first pass-gate transistor having a first gate structure electrically connected to a first word line extending parallel to the first gate structure, and a source/drain feature electrically connected to a first bit line extending perpendicular to the first gate structure; and a first pull-up transistor having a source electrically connected to a first VDD line extending perpendicular to the first gate structure. The second memory cell includes a second pass-gate transistor having a second gate structure electrically connected to a second word line extending parallel to the second gate structure and a source/drain feature electrically connected to a second bit line extending perpendicular to the second gate structure; and a second pull-up transistor having a source electrically connected to a second VDD line extending perpendicular to the second gate structure. The first VDD line and the first bit line are disposed in the same metal layer, the second VDD line and the second bit line are disposed in different metal layers, and the second word line is disposed over the first word line.

According to some embodiments, a semiconductor device is provided. The semiconductor device includes a first cell and a second cell. The first cell includes a first transistor having a first gate structure electrically connected to a first metal line extending parallel to the first gate structure, and a source/drain feature electrically connected to a second metal line extending perpendicular to the first gate structure; and a second transistor having a source electrically connected to a first VDD line extending perpendicular to the first gate structure. The second cell includes a third transistor having a second gate structure electrically connected to a third metal line extending parallel to the second gate structure, and a source/drain feature electrically connected to a fourth metal line extending perpendicular to the second gate structure; and a fourth transistor having a source electrically connected to a second VDD line extending perpendicular to the second gate structure. The first VDD line, the second metal line and the third metal line are disposed in a first metal layer closest to the first and second gate structures, and the first metal line, the second VDD line and the fourth metal line are disposed in a second metal layer over the first metal layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first memory cell, comprising:
a first pass-gate transistor, having a first gate structure electrically connected to a first word line extending parallel to the first gate structure, and a first source/drain feature electrically connected to a first bit line extending perpendicular to the first gate structure; and
a first pull-up transistor, having a first source electrically connected to a first VDD line extending perpendicular to the first gate structure; and
a second memory cell, comprising:
a second pass-gate transistor, having a second gate structure electrically connected to a second word line extending parallel to the second gate structure, and a second source/drain feature electrically connected to a second bit line extending perpendicular to the second gate structure; and
a second pull-up transistor, having a second source electrically connected to a second VDD line extending perpendicular to the second gate structure,
wherein the first VDD line, the first bit line and the second VDD line are disposed in a first metal layer closest to the first and second gate structures, and the first word line and the second bit line are disposed in a second metal layer over the first metal layer.

2. The semiconductor device of claim 1, wherein an active region of the first pass-gate transistor is wider than an active region of the second pass-gate transistor.

3. The semiconductor device of claim 1, wherein the first and second memory cells have the same cell height, and a cell width of the first memory cell is greater than a cell width of the second memory cell.

4. The semiconductor device of claim 1, wherein the second word line is disposed in a third metal layer over the second metal layer.

5. The semiconductor device of claim 1, wherein the first memory cell further comprises a first pull-down transistor having a third source electrically connected to a first VSS line extending perpendicular to the first gate structure, and the second memory cell further comprises a second pull-down transistor having a fourth source electrically connected to a second VSS line extending perpendicular to the second gate structure, wherein the first VSS line and the second VSS line are disposed in different metal layers.

6. The semiconductor device of claim 5, wherein the second word line and the first VSS line are disposed in a third metal layer over the second metal layer, and the second VSS line is disposed in a fourth metal layer over the third metal layer.

7. The semiconductor device of claim 1, wherein the second gate structure is further electrically connected to a third word line extending parallel to the second gate structure and overlapping the second word line, and the second and third word lines are electrically connected in parallel and disposed in two adjacent metal layers.

8. The semiconductor device of claim 1, wherein the first memory cell is disposed in a first memory array, and the second memory cell is disposed in a second memory array separated from the first memory array.

9. A semiconductor device, comprising:
a first memory cell, comprising:
a first pass-gate transistor, having a first gate structure electrically connected to a first word line extending parallel to the first gate structure, and a first source/drain feature electrically connected to a first bit line extending perpendicular to the first gate structure; and
a first pull-up transistor, having a first source electrically connected to a first VDD line extending perpendicular to the first gate structure; and
a second memory cell, comprising:
a second pass-gate transistor, having a second gate structure electrically connected to a second word line extending parallel to the second gate structure, and a second source/drain feature electrically connected to a second bit line extending perpendicular to the second gate structure; and
a second pull-up transistor, having a second source electrically connected to a second VDD line extending perpendicular to the second gate structure,
wherein the first VDD line and the first bit line are disposed in the same metal layer, the second VDD line and the second bit line are disposed in different metal layers, and the second word line is disposed over the first word line.

10. The semiconductor device of claim 9, wherein an active region of the first pass-gate transistor is wider than an active region of the second pass-gate transistor.

11. The semiconductor device of claim 9, wherein the first and second memory cells have the same cell height, and a cell width of the first memory cell is greater than a cell width of the second memory cell.

12. The semiconductor device of claim 9, wherein the first VDD line, the first bit line and the second VDD line are disposed in a first metal layer closest to the first and second gate structures, and the second bit line is disposed in a second metal layer over the first metal layer.

13. The semiconductor device of claim 12, wherein the first word line is disposed in the second metal layer, and the second word line is disposed in a third metal layer over the second metal layer.

14. The semiconductor device of claim 9, wherein the first memory cell further comprises a first pull-down transistor having a third source electrically connected to a first VSS line extending perpendicular to the first gate structure, and the second memory cell further comprises a second pull-down transistor having a fourth source electrically connected to a second VSS line extending perpendicular to the second gate structure, wherein the first VSS line and the second VSS line are disposed in different metal layers.

15. The semiconductor device of claim 14, wherein the second word line and the first VSS line are disposed in the same metal layer, and the second VSS line is disposed over the first VSS line.

16. The semiconductor device of claim 9, wherein the second gate structure is further electrically connected to a third word line extending parallel to the second gate structure and overlapping the second word line, and the second and third word lines are electrically connected in parallel and disposed in two adjacent metal layers.

17. The semiconductor device of claim 9, wherein the first memory cell is disposed in a first memory array, and the second memory cell is disposed in a second memory array separated from the first memory array.

18. A semiconductor device, comprising:
a first cell, comprising:
a first transistor, having a first gate structure electrically connected to a first metal line extending parallel to the first gate structure, and a first source/drain feature electrically connected to a second metal line extending perpendicular to the first gate structure; and
a second transistor, having a first source electrically connected to a first VDD line extending perpendicular to the first gate structure; and
a second cell, comprising:
a third transistor, having a second gate structure electrically connected to a third metal line extending parallel to the second gate structure, and a second source/drain feature electrically connected to a fourth metal line extending perpendicular to the second gate structure; and
a fourth transistor, having a second source electrically connected to a second VDD line extending perpendicular to the second gate structure,
wherein the first VDD line, the second metal line and the third metal line are disposed in a first metal layer closest to the first and second gate structures, and the first metal line, the second VDD line and the fourth metal line are disposed in a second metal layer over the first metal layer.

19. The semiconductor device of claim 18, wherein the first and second cells have the same cell height, and a cell width of the first cell is greater than a cell width of the second cell.

20. The semiconductor device of claim 18, wherein the first cell further comprises a fifth transistor having a third source electrically connected to a first VSS line extending perpendicular to the first gate structure, and the second cell further comprises a sixth transistor having a fourth source electrically connected to a second VSS line extending perpendicular to the second gate structure, wherein the second VSS line is disposed in the second metal layer, and the first VSS line is disposed over the second VSS line.
